(19) United States
(12) Patent Application Publication
(10) Pub. No.: US 2025/0157952 A1
(43) Pub. Date: May 15, 2025

(54) SPACERS FOR BEOL MULTI-PATTERNING

(71) Applicants: ASM IP HOLDING B.V., Almere (NL); IMEC VZW, Leuven (BE)

(72) Inventors: Debanjan Jana, Leuven (BE); Yiting Sun, Leuven (BE); David De Roest, Leuven (BE); Daniele Piumi, Etterbeek (BE); Sara Paolillo, Leuven (BE); Philippe Bezard, Leuven (BE); Vincent Renaud, Leuven (BE)

(21) Appl. No.: 18/917,894

(22) Filed: Oct. 16, 2024

Related U.S. Application Data
(60) Provisional application No. 63/599,405, filed on Nov. 15, 2023.

(51) Int. Cl. H01L 23/64; H01L 21/02; H01L 21/311

(52) U.S. Cl. CPC H01L 23/647; H01L 21/02186; H01L 21/31122; H01L 21/31138; H01L 21/31144

(57) ABSTRACT

A method for forming an intermediate in the multiple patterning lithographic formation of a semiconductor device mask involves: 1) Providing a target layer; 2) Using EUV lithography to form mandrels on the target layer, with a pitch of less than 40 nm; 3) Depositing a conformal spacer material on the mandrels, narrowing the gaps between them; 4) Performing a directional etch to expose the top surface of the mandrels. The spacer material has a resistivity lower than 10⁴ Ω·cm at 20° C.

### CROSS-REFERENCE TO RELATED APPLICATIONS

The present application claims priority to U.S. Provisional Application No. 63/599,405, filed Nov. 15, 2023, which is hereby incorporated by reference in its entirety.

### FIELD OF THE INVENTION

The invention relates to the field of semiconductor device fabrication, and more specifically to multi-patterning lithographic techniques used in the Back-End-of-Line (BEOL) process.

### BACKGROUND OF THE INVENTION

In semiconductor device fabrication, particularly in Back-End-of-Line (BEOL) processes, multi-patterning lithographic techniques are commonly utilized to form patterns for metal interconnects. A key challenge in this area is the scaling down of the metal pitch, which is crucial for enabling higher transistor densities and improved device performance. Spacer-based multi-patterning schemes such as Self-Aligned Double Patterning (SADP) and Self-Aligned Quadruple Patterning (SAQP) have been used to meet the demand for smaller feature sizes. These techniques often struggle to achieve consistent critical dimensions (CDs), especially at pitches smaller than 40 nm. At these reduced sizes, depending on the choice of materials in the stack, different patterning issues might arise such as under-etch, lateral consumption, and line-bridging during spacer etch and post-etch processes. These challenges are specifically exacerbated at pitch sizes below 40 nm and were negligible at larger pitches. Consequently, there is a pressing need for improved methods that can deliver both consistent and reduced metal pitch dimensions.

### SUMMARY OF THE INVENTION

It is an object of the present invention to provide an effective method for achieving very small metal pitches in Back-End-of-Line (BEOL) semiconductor fabrication processes, aiming to overcome limitations associated with critical dimension variability.

The above objective is accomplished by methods using Extreme Ultraviolet (EUV) lithography and low resistivity spacers, according to the present invention.

In the first aspect, the present invention relates to a method using EUV lithography for forming an intermediate in the multiple patterning lithographic formation of a mask for patterning a target layer during the fabrication of a semiconductor device, comprising:
a. Providing the target layer, then
b. Forming mandrels on the target layer using EUV lithography, said mandrels being separated by gaps, wherein the pitch between the mandrels is less than 40 nm, then
c. Conformally depositing a spacer material on all exposed surfaces of the mandrels, and on exposed top surfaces of the target layer present in the gaps, thereby partly narrowing the gaps, and then
d. Performing a directional etch of the spacer material so as to expose a top surface of the mandrels and a top surface of the target layer present in the gaps,
wherein the spacer material has a resistivity lower than 10⁴ Ω·cm at 20° C.

In the second aspect, the present invention relates to a multiple patterning lithographic method using EUV lithography for patterning a target layer during the fabrication of a semiconductor device, the method comprising the method according to any embodiments of the first aspect, followed by the following steps:
e. Filling the narrowed gaps with a filling material so that the top surface of the spacer is exposed,
f. Removing the spacer material, thereby leaving on the layer a mask formed by the combination of the mandrels and of the filling material, and
g. Patterning the target layer by using the mask.

In the third aspect, the present invention relates to an intermediate in the multiple patterning lithographic formation of a mask for patterning a target layer during the fabrication of a semiconductor device, comprising:
a. a target layer,
b. mandrels on the target layer, wherein the pitch between the mandrels is less than 40 nm,
c. spacers on side walls of the mandrels, wherein spacers on neighbouring mandrels are separated by a gap, and
wherein the top of the mandrels is exposed and wherein the spacer material has a resistivity lower than 10⁴ Ω·cm at 20° C.

It is an advantage of embodiments of the present invention that the method allows for more consistent critical dimensions, which is particularly beneficial when working with pitches smaller than 40 nm, e.g., smaller than 25 nm.

It is an advantage of embodiments of the present invention that the flexibility in the choice of spacer materials allows these materials to be tailored for specific applications.

It is an advantage of embodiments of the present invention that, although the method is particularly suitable for use in the Back-End-of-Line (BEOL) process, it may be used in other stages of semiconductor device fabrication as well.

It is an advantage of embodiments of the present invention that the method facilitates the downscaling of the metal pitch to very small sizes. This aids in the ongoing miniaturization of semiconductor devices.

It is an advantage of embodiments of the present invention that the chosen spacer materials and methods are particularly effective in minimizing issues like under-etch, lateral consumption, and line-bridging, thereby contributing to less variability and enhanced reliability in the manufacturing process.

It is an advantage of embodiments of the present invention that they achieve straight profile post spacer etching at below 40 nm pitches.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change, and evolution of devices in this field, the present concepts are believed to represent substantial new and novel improvements, including departures from prior practices, resulting in the provision of more efficient, stable, and reliable devices of this nature.

The above and other characteristics, features, and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 shows a series of vertical cross-sections of schematic representations of intermediate resulting from steps in a method according to aspects of the present invention.

FIG. 2 shows representations of transmission electron microscopy pictures of vertical cross-sections through intermediates obtainable a) in the prior art, and b), c), and d) in embodiments of the present invention with spacers of decreasing resistivity (from left to right).

FIG. 3 is a flowchart representing the first and second aspects of the present invention.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third, and the like in the description and in the claims, are used for distinguishing between similar elements and not necessarily for describing a sequence, either temporally, spatially, in ranking, or in any other manner. It is to be understood that the terms so used are interchangeable under appropriate circumstances and that the embodiments of the invention described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps, or components as referred to, but does not preclude the presence or addition of one or more other features, integers, steps or components, or groups thereof. The term “comprising” therefore covers the situation where only the stated features are present (and can therefore always be replaced by “consisting of” in order to restrict the scope to said stated features) and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures, or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures, and techniques have not been shown in detail in order not to obscure an understanding of this description.

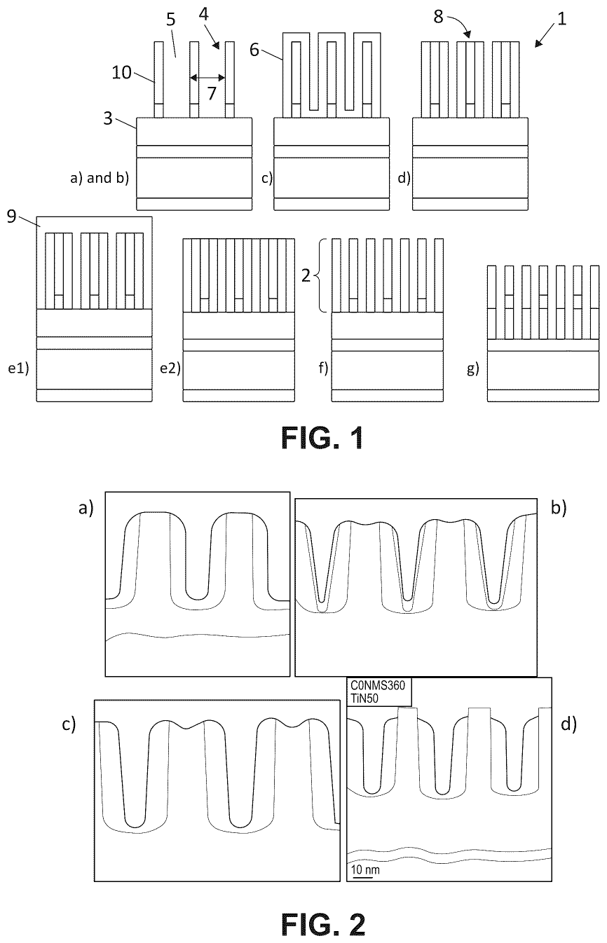

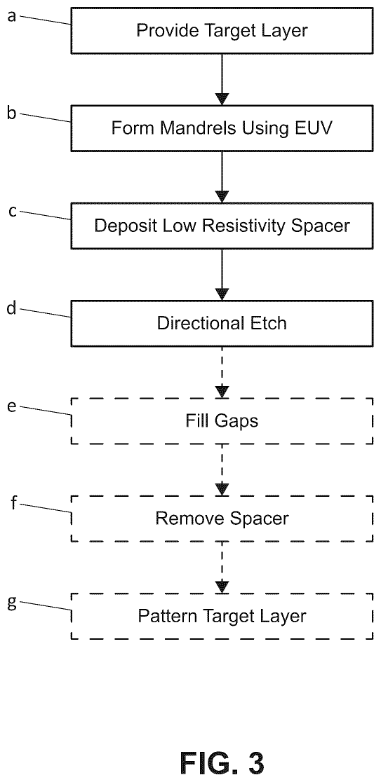

We now refer to FIG. 1 (a to d) and FIG. 3 (solid lines). In the first aspect, the present invention relates to a method using EUV lithography for forming an intermediate (1) in the multiple patterning lithographic formation of a mask (2) for patterning a target layer (3) during the fabrication of a semiconductor device, comprising:
a. Providing the target layer (3), then
b. Forming mandrels (4) on the target layer (3) using EUV lithography, said mandrels (4) being separated by gaps (5), wherein the pitch (7) between the mandrels (4) is less than 40 nm, then
c. Conformally depositing a spacer material (6) on all exposed surfaces of the mandrels (4) and on exposed top surfaces of the target layer (3) present in the gaps (5), thereby partly narrowing the gaps (5), and then
d. Performing a directional etch of the spacer material (6) so as to expose a top surface (8) of the mandrels (4) and a top surface of the target layer (3) present in the gaps (5),
wherein the spacer material (6) has a resistivity lower than 10⁴ Ω·cm at 20° C.

This is advantageous because the lower resistivity helps in achieving less ion deflection or charge consumption, enabling more precise etching. In this context, the term ‘resistivity’ refers to the intrinsic property of a material to oppose the flow of electric current. The 10⁴ Ω·cm threshold was chosen because materials below it have sufficient electrical conduction to achieve improved etching.

EUV lithography, which stands for Extreme Ultraviolet lithography, is a critical technology in the fabrication of semiconductor devices. It is a specialized form of photolithography that uses extremely short wavelengths of light, usually between 10 and 15 nm, and most commonly specifically around 13.5 nm, to transfer intricate patterns from a photomask onto a substrate. This technology allows for the creation of features with dimensions below 40 nm, and typically well below 25 nm. The capability to define such small features makes EUV lithography indispensable for achieving higher density patterning and more efficient use of the substrate surface.

The process of EUV lithography employs specialized optics coated with multi-layers that are capable of reflecting EUV light. The substrate is coated with a photoresist that is specifically sensitive to EUV radiation. Upon exposure to EUV light, the photoresist undergoes a chemical transformation, enabling subsequent etching or other post-exposure processes to take place. The photoresist used in embodiments of this invention, referred to as an “EUV-sensitive resist,” contains chemical compounds that are particularly reactive to the shorter wavelengths of EUV light. For example, the EUV-sensitive photoresist could be a chemically amplified resist, a metal oxide-based resist, or a hybrid resist sensitive to extreme ultraviolet wavelengths.

In embodiments, the mandrels may be formed of one or more materials on which the spacer material can be deposited conformally. Preferably, the one or more materials of the mandrels allow the spacer material to be removed selectively with respect to the mandrels. An example material for forming the mandrels is amorphous silicon. An adhesion layer (e.g. SiO₂) can be present between the amorphous silicon and the target layer.

In embodiments, the mandrels may have a width of from 5 to 20 nm.

In embodiments, the mandrels may have a height of from 20 to 100 nm.

In embodiments, the mandrels may have a length of from 1 μm to 1 cm.

In embodiments, the aspect ratio (height/width) of the mandrels may be from 1 to 5.

In embodiments, the mandrels may be arranged parallel to each other and regularly spaced.

In the context of the present invention, the term ‘target layer’ refers to a layer within the semiconductor device that is subjected to patterning. The target layer could be either a layer that will be present in a patterned form in the completed semiconductor device or it could be a hard mask that will serve to transfer a pattern in an underlying layer and that will not be present in the completed semiconductor device. The target layer is preferably chosen so that spacer materials can be selectively removed without damaging the target layer. In embodiments, the material of the target layer can be selected from metals, insulators and semiconductors. Preferably, the target layer is a hard mask layer. More preferably, it is a hard mask layer that, once patterned, can be used to pattern an underlying layer. The underlying layer can, for instance, be a metal layer (e.g., a Ru layer). In embodiments, the intermediate obtained by the method of the first aspect can be used in a method for patterning the underlying layer, wherein the patterned target layer is a patterned hard mask and wherein the pattern of the hard mask is transferred in the underlying layer. In these embodiments, the underlying layer may be selected from metals, insulators, and semiconductors but it is preferably a metal, e.g., ruthenium.

In embodiments, the target layer (3) provided in step a is provided over an underlying layer. This underlying layer can be destined to be patterned by using the patterned target layer as a further mask.

In embodiment, the target layer may have a thickness of from 1 nm to 1 μm.

In embodiments, the spacer material (6) may have a resistivity lower than 1 Ω·cm, preferably lower than 1 mΩ·cm at 20° C.

This is advantageous because it further minimizes ion deflection and charge consumption, improving the etching process. The lower resistivity levels such as 1 Ω·cm or even 1 mΩ·cm are particularly beneficial when very precise etching is required, often achievable through materials like Ti, Ru, titanium nitride (TiN) or tantalum nitride (TaN).

In embodiments, the spacer material (6) may be a ceramic material.

This is advantageous because ceramic materials are generally stable and can withstand high temperatures and corrosive environments. Ceramic materials, in this context, refer to inorganic, non-metallic solids that are typically produced using heat. They include materials like silicon carbide and aluminum oxide, known for their hardness and high melting points, making them suitable for spacer materials.

In embodiments, the ceramic material may be a nitride or an oxinitride, such as TiN, TiON, TaN, ZrN, and Cu₃N. Preferably, it is a nitride.

This is advantageous because nitrides usually have excellent thermal and chemical stability, enhancing process compatibility. Nitrides are a class of materials where the anion is nitrogen. These materials often exhibit properties like high thermal stability and resistance to chemical attack, which make them desirable for high-temperature and chemically aggressive environments. Furthermore, their resistivity tends to be lower than the resistivity of the corresponding oxides.

In embodiments, the spacer material (6) may be TiN.

The ‘spacer material’ specified in the invention is characterized by its electrical resistivity. The material may include metals like titanium nitride (TiN), tantalum nitride (TaN), or semi-metallic compounds like titanium oxynitride (TION).

This is advantageous because, due to its low resistivity, TiN has shown to produce the straightest profiles during etching compared to other materials, reducing CD variability. TiN is specifically advantageous as it combines low resistivity with excellent thermal and chemical stability, making it highly effective in the semiconductor manufacturing process.

In embodiments, the step of conformally depositing a spacer material (6) on all exposed surfaces of the mandrels (4) also results into depositing the spacer material on exposed surfaces of the target layer (3) present in the gaps (5).

In embodiments, step c may be performed by CVD, ALD, or PVD, preferably CVD or ALD.

We now refer to FIG. 2 which shows representations of TEM pictures of intermediates obtained according to embodiments of the first aspect. In these experiments, a range of materials was tested for spacer applications: TiO₂ (a), TiON with lower nitrogen content (b), TiON with higher nitrogen content (c), and pure TiN film (d). Distinct performance characteristics for each material were observed in the experiments.

In the case of TiO₂, it was noted that the top part of the post-etch profile was fully open, while the bottom remained closed. A clear indication that the ions did not reach the bottom of the spacers. At this juncture, it is worth noting that increasing ion energy to facilitate etching at the bottom of the spacers is not a viable option. Such an approach would result in significant consumption of both the mandrel and spacer height. When TiON with lower nitrogen content was examined, a modest opening at the bottom was identified, and a more tapered profile was displayed. This tapered profile results from the over-etching conditions employed to open the bottom. If such over-etching conditions were used with TiO₂ spacers, post-etch tapered profile would likely have resulted as well. A significant improvement in the profile was observed when the nitrogen content in TiON was increased, outperforming the profile of the TiON with lower nitrogen content, and reaching a larger opening at the bottom.

Most notably, the best performance among all the tested materials was achieved by the pure TiN film, particularly in maintaining the straightness of both the space critical dimensions (CD) and line CD, but also in term of opening at the bottom. These attributes were identified as particularly advantageous for the efficacy of subsequent processing steps.

A clear trend was discerned from the results: a transition from dielectric spacer materials to conductive or metallic spacers led to enhanced control over the post-etch profile.

The term ‘pitch’ is used to define the distance between adjacent mandrels. Specifically, it may refer to either the center-to-center distance or the edge-to-edge distance between adjacent mandrels.

In embodiments, the pitch (7) between the mandrels (4) may be less than 20 nm, preferably less than 18 nm.

This is a feature advantageously achievable by the method of the present invention. It is advantageous because a tighter pitch allows for greater device integration and potential performance gains. The term ‘pitch’ in this embodiment refers specifically to the edge-to-edge distance between adjacent mandrels, allowing for enhanced device miniaturization.

The ‘directional etch’ refers to an etching process where material is preferentially removed in a specific orientation. This could be achieved using methods such as deep reactive ion etching (DRIE) or directional wet etching.

In the typical situation where the step c of conformally depositing a spacer material (6) on all exposed surfaces of the mandrels (4) also results into depositing the spacer material on exposed top surfaces of the target layer (3) present in the gaps (5), step d of performing a directional etch of the spacer material (6) may be so as to expose a top surface of the mandrels (4) and a top surface of the target layer (3) present in the gaps (5).

In embodiments, step d is performed so as to also expose a top surface of the target layer.

In embodiments, the directional etch may comprise contacting the spacer material (6) with an ionized gas.

This is advantageous because ionized gas enables more precise and controlled etching of low resistivity materials. An ionized gas, often referred to as plasma, is advantageous for etching as it can be controlled easily by electrical fields, thus allowing for highly precise etching processes.

The term ‘ionized gas’ encompasses gases that have been ionized through various methods. Acceptable gases could include argon, nitrogen, oxygen, hydrogen, or Halogen-based gases, e.g., fluorine-based gases like CF₄ or SF₆. For instance, a combination of a halogen containing gaseous molecule and either oxygen or argon. The ionization may, for instance, be achieved through methods such as RF plasma generation.

In embodiments, the directional etch may comprise a vertical bombardment of the spacer material (6) with ions.

This is advantageous because vertical bombardment enable straighter post-etch profiles, reducing variability. The term ‘vertical bombardment’ refers to the directionality of the ions with respect to the surface normal of the material being etched, and is beneficial for achieving straight profiles.

‘Vertical bombardment’ refers to the process in which ions are directed perpendicularly toward the surface of the target layer. This could be achieved during ion implantation processes.

In embodiments, the vertical bombardment may be followed by a wet etch. This results in directional wet etching. This is especially advantageous when the spacer material does not etch well by ion bombardment alone. For instance, after ion bombardment, Cu or Zn still benefits from a subsequent wet etch for removing the parts of the spacers that have been exposed to the ion bombardment. This ensuring cleaner profiles. The ‘wet etch’ refers to the use of liquid chemicals or solvents to remove material and is considered advantageous as it complements ion bombardment, often necessary for materials like copper (Cu) or Zinc (Zn).

In embodiments, step d may comprise d1. Subjecting said spacer material (6) to ion bombardment to modify a surface layer thereof; d2. Removing said modified surface layer using a liquid etchant, d3. If the top surface of the mandrels (4) is not exposed, repeating steps d1 and d2 until it is the case. In embodiments, the ion bombardment used in step d1 may comprise ions of oxygen or hydrogen.

In embodiments, the vertical bombardment may be part of a vertical reactive ion etching process, wherein the ion energies in the reactive ion etching process may be from 20 to 50 eV.

This is an advantage of the present invention that it is compatible with the use of low ion energies. ‘Reactive ion etching’ is a type of dry etching which uses chemically reactive plasma to remove material. The energy levels mentioned (20 to 50 eV) are suitable for ensuring efficient yet controlled etching.

In embodiments, the target layer (3) may be a conductive layer, an insulator layer, or a semiconductor layer. Typically, it is a hard mask layer. Typically, the hard mask layer will be, later in the fabrication of the semiconductor device, used to pattern an underlying layer, such as a metal (e.g., Ru) layer. This is advantageous because metal layers are commonly used in semiconductor devices for electrical connections, providing a broad range of applications for the invention. The term ‘metal layer’ refers to layers composed of metals like copper, aluminum, ruthenium, or tungsten, which are commonly used for electrical interconnections within the semiconductor device.

In embodiments, the method may be performed during the Back-End-of-Line stage of the semiconductor device fabrication.

This is advantageous because integrating the method at the BEOL stage allows for fine-tuning of interconnects, which is advantageous for device performance. The Back-End-of-Line (BEOL) stage typically involves processes that occur after the completion of the front-end processes, like the formation of the transistors. This stage primarily focuses on metal layers and interconnects and is critical for device performance.

In embodiments, step b. of forming the mandrels (4) on the target layer (3) may comprise:
b1. Forming over the target layer (3) a mandrel material layer,
b2. Forming a layer of EUV-sensitive resist over the mandrel material layer,
b3. Exposing the EUV-sensitive resist to EUV light through a mask, said mask containing a pattern designed to achieve a pitch of less than 40 nm between the mandrels after step b5,
b4. Developing the exposed EUV-sensitive resist, thereby forming a resist mask having a pattern,
b5. Etching the mandrel material layer using the resist mask as an etching mask, thereby transferring the pattern into the mandrel material layer,
b6. Removing the resist mask.

Steps a to d are always performed, independently of the type of multiple patterning lithographic method used.

Multiple patterning lithographic formation is a technique used in semiconductor fabrication to create patterns with feature sizes smaller than what can be achieved with a single lithographic exposure. The method involves sequential lithographic and etching or deposition processes to refine or augment an initial pattern. In essence, it's an iterative approach to increase the density of features on a semiconductor substrate.

This technique is particularly advantageous for extending the utility of existing lithography methods, such as EUV lithography in the context of the present invention, by effectively reducing the minimum feature size beyond the intrinsic limits of the lithography system. This is especially critical when targeting very small dimensions, such as the pitch of less than 40 nm between the mandrels as used herein.

The process generally starts with the formation of an initial pattern, often referred to as “mandrels,” on a target layer using a lithographic process. The mandrels act as a template for subsequent processing steps. A spacer material is then conformally deposited around these mandrels, followed by a directional etching process that leaves behind new features between the original mandrels. These additional features further reduce the effective feature size and pitch, allowing for the creation of smaller, more closely packed features on the target layer.

The specific type of multiple patterning used can vary and may include techniques such as double patterning or quadruple patterning, depending on the requirements for feature size and density. Each iteration allows for greater miniaturization and more complex circuit designs.

At the end of step d, the top surface of the mandrels is exposed. Preferably, also, the top of the target layer is exposed between adjacent spacers.

We now refer to FIG. 1 (e1 to g) and FIG. 3 (dashed lines). In the second aspect, the present invention relates to a multiple patterning lithographic method using EUV lithography for patterning a target layer (3) during the fabrication of a semiconductor device, the method comprising the method according to any embodiments of the first aspect, followed by the following steps:
e. Filling the narrowed gaps (5) with a filling material (9) so that the top surface (8) of the spacer is exposed,
f. Removing the spacer material (6), thereby leaving on the layer a mask (2) formed by the combination of the mandrels (4) and of the filling material (9), and
g. Patterning the target layer by using the mask (2).

The ‘filling material’ is used to occupy the spaces between spacers and could be composed of various materials. Examples include inorganic dielectrics like silicon dioxide or metals like copper. The filling material is chosen so that the spacer material can be removed selectively with respect to the filling material.

Similarly, the material of the mandrels is preferably chosen so that the spacer material can be removed selectively with respect to the material of the mandrels.

In embodiments, step e may be performed by overfilling the narrowed gaps (5) (step e1) with a filling material (9), followed by chemical mechanical planarization (step e2), so that the top surface (8) of the spacer is exposed.

In the third aspect, the present invention relates to an intermediate (1) in the multiple patterning lithographic formation of a mask (2) for patterning a target layer (3) during the fabrication of a semiconductor device, comprising:
a. a target layer (3),
b. mandrels (4) on the target layer (3), separated by gaps (5), wherein the pitch between the mandrels is less than 40 nm,
c. a spacer material (6) on all exposed surfaces of the mandrels (4), and
wherein the spacer material (6) has a resistivity lower than 10⁴ Ω·cm at 20° C.

Any feature of the third aspect can be as correspondingly described in any of the two other aspects.

It is to be understood that although preferred embodiments, specific constructions and configurations, as well as materials, have been discussed herein for devices according to the present invention, various changes or modifications in form and detail may be made without departing from the scope of this invention. Steps may be added or deleted to methods described within the scope of the present invention.

What is claimed is:

1. A method using EUV lithography for forming an intermediate (1) in the multiple patterning lithographic formation of a mask (2) for patterning a target layer (3) during the fabrication of a semiconductor device, comprising:
a) Providing the target layer (3), then
b) Forming mandrels (4) on the target layer (3) using EUV lithography, said mandrels (4) being separated by gaps (5), wherein the pitch (7) between the mandrels (4) is less than 40 nm, then
c) Conformally depositing a spacer material (6) on all exposed surfaces of the mandrels (4) and on exposed top surfaces of the target layer (3) present in the gaps (5), thereby partly narrowing the gaps (5), and then
d) Performing a directional etch of the spacer material (6) so as to expose a top surface (8) of the mandrels (4) and a top surface of the target layer (3) present in the gaps (5),
wherein the spacer material (6) has a resistivity lower than 10⁴ Ω·cm at 20° C.

2. The method according to claim 1, wherein the spacer material (6) has a resistivity lower than 1 Ω·cm, preferably lower than 1 mΩ·cm at 20° C.

3. The method according to claim 1, wherein the spacer material (6) is a ceramic material.

4. The method according to claim 3, wherein the ceramic material is a nitride.

5. The method according to claim 4, wherein the nitride is selected from TiN, TaN, ZrN, and Cu₃N.

6. The method according to claim 5, wherein the spacer material (6) is TiN.

7. The method according to claim 1, wherein the pitch (7) between the mandrels (4) is less than 25 nm, preferably less than 20 nm, more preferably less than 18 nm.

8. The method according to claim 1, wherein the directional etch comprises contacting the spacer material (6) with an ionized gas.

9. The method according to claim 8, wherein the directional etch comprises a vertical bombardment of the spacer material (6) with ions.

10. The method according to claim 9, wherein the vertical bombardment is followed by a wet etch.

11. The method according to claim 9, wherein the vertical bombardment is part of a vertical reactive ion etching process.

12. The method according to claim 11, wherein the ion energies in the reactive ion etching process are from 20 to 50 eV.

13. The method according to claim 1, wherein the target layer (3) is a hard mask layer (3).

14. The method according to claim 1, performed during the Back-End-of-Line stage of the semiconductor device fabrication.

15. The method according to claim 1, wherein step b) of forming the mandrels (4) on the target layer (3) comprises:
b1) Forming over the target layer (3) a mandrel material layer;
b2) Forming a layer of EUV-sensitive resist over the mandrel material layer;
b3) Exposing the EUV-sensitive resist to EUV light through a mask, said mask containing a pattern designed to achieve a pitch of less than 40 nm between the mandrels after step b5;
b4) Developing the exposed EUV-sensitive resist, thereby forming a resist mask having a pattern;
b5) Etching the mandrel material layer using the resist mask as an etching mask, thereby transferring the pattern into the mandrel material layer; and
b6) Removing the resist mask.

16. The method according to claim 1, wherein step d is performed so as to also expose a top surface of the target layer.

17. The method according to claim 1, followed by the following steps:
e) Filling the narrowed gaps (5) with a filling material (9) so that the top surface (8) of the spacer is exposed;
f) Removing the spacer material (6), thereby leaving on the layer a mask (2) formed by the combination of the mandrels (4) and of the filling material (9); and
g) Patterning the target layer (3) by using the mask (2).

18. An intermediate (1) in the multiple patterning lithographic formation of a mask (2) for patterning a target layer (3) during the fabrication of a semiconductor device, comprising:
a) a target layer (3);
b) mandrels (4) on the target layer (3), wherein the pitch (7) between the mandrels (4) is less than 40 nm; and
c) spacers (6) on side walls of the mandrels (4),
wherein spacers (6) on neighboring mandrels (4) are separated by a gap (5),
wherein the top of the mandrels (4) is exposed, and
wherein the spacer material (6) has a resistivity lower than 10⁴ Ω·cm at 20° C.
